(19) United States
(12) Patent Application Publication
(10) Pub. No.: US 2006/0255717 A1
(43) Pub. Date: Nov. 16, 2006

(54) Polychromatic electroluminescent element and method for the production thereof

(76) Inventors: Manfred Hartmann, Ziegelberg/Petershausen (DE); Oliver Narwark, Munich (DE)

Correspondence Address: WILLIAM COLLARD;COLLARD & ROE, P.C., 1077 NORTHERN BOULEVARD, ROSLYN, NY, 11576, US

(21) Appl. No.: 10/568,921

(22) PCT Filed: Jul. 28, 2004
(86) PCT No.: PCT/EP04/08462

§ 371 Date: Mar. 31, 2006

(30) Foreign Application Priority Data
Aug. 21, 2003 (DE) 103 38 502.9

(51) Int. Cl. H05B 33/14; H01L 51/50

(52) U.S. Cl. 313/503; 313/506

(57) ABSTRACT

The invention relates to an electroluminescent film providing a particularly advantageous compromise between the safe functioning and simplified production thereof. The inventive polychromatic electroluminescent element consists of three similar electroluminescent films which contain dispersed electroluminophors and whose colors are not different from each other. The different colors are obtainable by an additional color mixture by means of a separate electric excitation of each electroluminescent film. Each of the films essentially comprises a support made of PET or other plastic material on which an electrode layer is vapour-deposited or cathode-sputtered, a luminous layer on which a rear transparent electrode is placed by serigraphy and laminated by means of an insulating foil.

The present invention relates to a polychromatic electroluminescent element and a method for its production.

Electroluminescence technology has increasingly gained in significance in recent time. It allows the implementation of almost arbitrarily large homogeneous illuminated areas which are free of screens and shadows. At the same time, power consumption and overall depth are extremely low (in the magnitude of one millimeter and less). The typical applications include, in addition to the background illumination of liquid crystal displays, the backlighting of transparent films which are provided with inscriptions and/or graphics.

Electroluminescence (in short: EL) is understood as the direct luminescence excitation of luminescent pigments and/or luminophores through an electric alternating field. Electroluminescence elements (in short: EL elements) based on thick-film technology using inorganic luminescent pigments and/or luminophores and AC voltage excitation have become widespread. In relation to thin-film EL elements, thin-layer EL elements are less complex and thus more cost-effective to produce.

The luminescent pigments and/or luminophores are embedded in a transparent organic or ceramic binder. Starting materials are usually zinc sulfides, which generate different, relatively narrow band emission spectra as a function of the doping and/or co-doping and preparation procedure. The focus of the spectrum determines the particular color of the emitted light.

The exciting AC voltage field typically has a frequency of a few hundred hertz, the effective value of the operating voltage frequently being in a range from approximately 50 to 150 volts. By elevating the voltage, a higher light density may typically be achieved, which is usually in a range from approximately 50 to approximately 200 candelas per square meter. A frequency increase usually causes a color shift toward lower wavelengths. However, both parameters must be tailored to one another to achieve a desired light impression.

In principle, two types of electrodes suggest themselves above all in the manufacturing of thick-film EL elements using AC voltage excitation. Firstly, these are indium-tin oxide electrodes (ITO) sputtered or vapor-deposited on plastic films in vacuum. They are very thin (a few hundred Å) and offer the advantage of high transparency at a relatively low resistance per unit area (approximately 60 to 600 ohm). However, they are not applicable to textured surfaces having steps, are less deformable, and are not applicable to substrates which outgas easily in vacuum. In addition, printing pastes having ITO or ATO (antimony-tin oxide) or intrinsically conductive transparent polymer pastes may be used. At a thickness of approximately 5 to 20 μm, electrodes of this type offer only lesser transparency at a high resistance per unit area (up to 50 kohm). However, they are largely applicable to any arbitrary texture, and even to textured surfaces. Furthermore, they may be laminated relatively well and deformed in a restricted way.

The service life of an EL element is limited. It is a function above all of the level and frequency of the AC voltage applied, in addition, however, also of environmental influences, particularly the effects of moisture and UV radiation. The service life of an EL element is typically specified as a half-life of the luminescent pigments. This is the time after which the light density has fallen to half of the starting value under the influences of the electrical field with unchanged operating conditions. In practice, the light density decreases to half of the original value within approximately 2000 to 3000 operating hours.

The emission color of an EL element may be tailored to the desired color impression through multiple possible measures. These include doping and co-doping of the luminescent pigments, mixing two or more EL pigments, adding one or more organic and/or inorganic color-converting and/or color-filtering pigments, coating the EL element using organic and/or inorganic color-converting and/or color-filtering substances, admixing colorants to the polymer matrix in which the luminescent pigments are dispersed, and the incorporation of a color-converting and/or color-filtering layer or film in the structure of the EL element.

Luminophores which emit a pure white are not currently available. For this reason, whitely luminescent EL elements are frequently produced with the aid of a mixture of at least two luminescent pigments, whose emissions (approximately) result in white when added. In order to obtain pure white, the use of an organic conductive lacquer having a slight blue coloration is typically necessary. However, the different aging of the two luminescent pigments causes a change of the color impression in the course of the service life, which is often very disturbing or unacceptable for the planned application. Furthermore, approximately white-luminescent luminophores exist, which contain toxic zinc selenides, however, and are therefore undesirable for use.

There is frequently a need for EL elements which may luminesce polychromatically, i.e., alternately in different colors as a function of an external controller.

Corresponding EL elements are referred to as polychromatic electroluminescent elements.

Polychromatic electroluminescent elements are known from, among other things, EP-A-1045618. A polychromatic EL light is described therein, in which different colors result through additive color mixing, in that at least two electroluminescent layers, which contain luminescent pigments, lying one over another are activated appropriately using at least three electrode layers. Electrodes are produced using vapor deposition of ITO on a PET substrate for this purpose, while in contrast all further layers, i.e., also all further electrodes, are produced using screen printing.

A multilayered EL element having different patterns and many luminescent colors is also described in EP-A-0998171. Here as well, the first transparent electrode is produced using vapor deposition or sputtering on a PET film. All further electrodes are produced using printing of optically transparent pastes.

A polychromatic EL element, which has multiple light-transparent electrode layers and multiple luminescent layers having different colors, is known from EP-A-0973358. A printed multilayered structure is also implemented according to this publication.

Constructions using multiple luminescent layers produced using screen printing, which all known polychromatic EL elements listed share in principle, are connected to some problems. In industrially common and available electroluminophores, usually particle diameters of greater than 20 μm, typically between 20 and 35 μm, and a broad particle size distribution must be expected. Therefore, luminescent layer thicknesses of 40 to 60 μm are typical. If coarse-grain pigments of this type are now dispersed in screen printing inks and applied in multiple layers on a carrier substrate, it is obvious that a very uneven surface results at typical degrees of filling of 65 to 75 weight-percent. The unevenness is caused by the scatter breadth of the particle dimensions and, in addition, by the evaporation of solvent during the drying procedure. The unevenness of the surface of each individual layer may be reduced by using UV-curable polymer binders and/or by using fine-grained luminescent pigments and/or luminescent pigments having a narrower particle size distribution, for example. These problems may thus be controlled in EL elements which are only provided with one luminescent layer and therefore emit monochromatically. However, in multilayered constructions, the unevenness of the individual layers adds statistically, so that a polychromatic EL element providing a homogeneous light impression is producible in practice only with significant outlay or not at all in the way described.

Furthermore, an additional leveling printing procedure and/or a leveling lamination procedure may be performed. In typical EL elements, the disadvantages of process steps of this type outweigh their advantages, however, since each additional layer reduces the electrical alternating field implemented, and pigment particles projecting during a lamination procedure may press into the polymer layer lying underneath, but may just as well penetrate the dielectric insulation and may thus influence the function of the particular EL element very disadvantageously.

In addition to these problems of unevenness, there is also the necessity of leading the individual planar electrodes to typically laterally positioned terminal areas. This results, in a multilayered construction on a substrate generated through screen printing, in layer heights of up to more than 100 μm having to be overcome, which may not be achieved by ITO or ATO screen printing pastes through simple printing and, if busbar printed formations using silver pastes are employed, results in a further increase of the unevenness of the surface. This is because, even with a single luminescent layer of the above-mentioned typical thickness, insulation layers and/or dielectric layers must be led very carefully over the layer edges in order to then also be able to lead a return electrode having good electrical conductivity properties over a layer edge of this type.

Therefore, the entire production of typical polychromatic EL elements, but particularly the production of the electrical wiring and/or the terminals of diverse fields in segmented luminescent layers is extremely difficult to manage and very susceptible to flaws.

In consideration of the problems described, it is the object of the present invention to provide a polychromatic electroluminescent element which may assume different light colors as a function of the electrical activation and nonetheless is producible at acceptable outlay in high quality. The object is connected thereto of providing a suitable production method for polychromatic EL elements which allows high product quality at a low reject rate.

According to one aspect of the present invention, this object is achieved by a polychromatic electroluminescent element according to claim 1. Contrary to the related art, according to which polychromatic electroluminescent elements are implemented as a multilayered screenprinted structure on one film, the polychromatic electroluminescent element according to the present invention is constructed from at least two electroluminescent films each having a luminescent layer. In this case, an electroluminescent film is to be understood as a coherent film body having a certain dimensional stability, which results because the luminescent layer of the electroluminescent film is applied to a stable film substrate (as a carrier) and/or comprises a preferably cast film itself, in whose matrix the dispersed luminophores are embedded. This has the decisive advantage that during the production, each electroluminescent film may be provided separately with the required electrode layer or layers, and the entire construction does not have to be performed sequentially “from bottom to top”. The problems described above with the wiring of the electrodes are thus largely dispensed with. In particular, the terminals of the electrodes on the individual electroluminescent films may be designed separately according to manageable technologies typical for normal monochromatic electroluminescent elements.

Different colors are generated through additive color mixing in that each luminescent layer, which emits in a different color, is excited differently through a separately controlled electrical alternating field in each case. With three electroluminescent films in the colors red, green, and blue, the entire color spectrum, including white, may thus be represented with appropriate activation.

Preferred embodiments of the present invention are implemented according to claims 2-22.

According to a further aspect of the present invention, the object is achieved by a method for producing a polychromatic electroluminescent element according to claim 23. In contrast to the related art, in this case all individual layers of the EL element are not applied sequentially one on top of another, “from bottom to top” using printing, but rather at least two prefinished electroluminescent films are joined through lamination, for example. The problems described above with the wiring of the electrodes are thus largely dispensed with. In particular, the terminals of the electrodes on the individual electroluminescent films may be produced separately according to manageable technologies typical for normal monochromatic electroluminescent elements before being joining.

Preferred embodiments of the method according to the present invention are implemented according to claims 24-26.

Examples of preferred embodiments of the present invention will be explained in greater detail on the basis of the attached figures. The figures are purely schematic sectional illustrations which are not to scale, in particular, layer thicknesses are greatly enlarged for reasons of clarity. The area of the electrode terminals is not shown in each case.

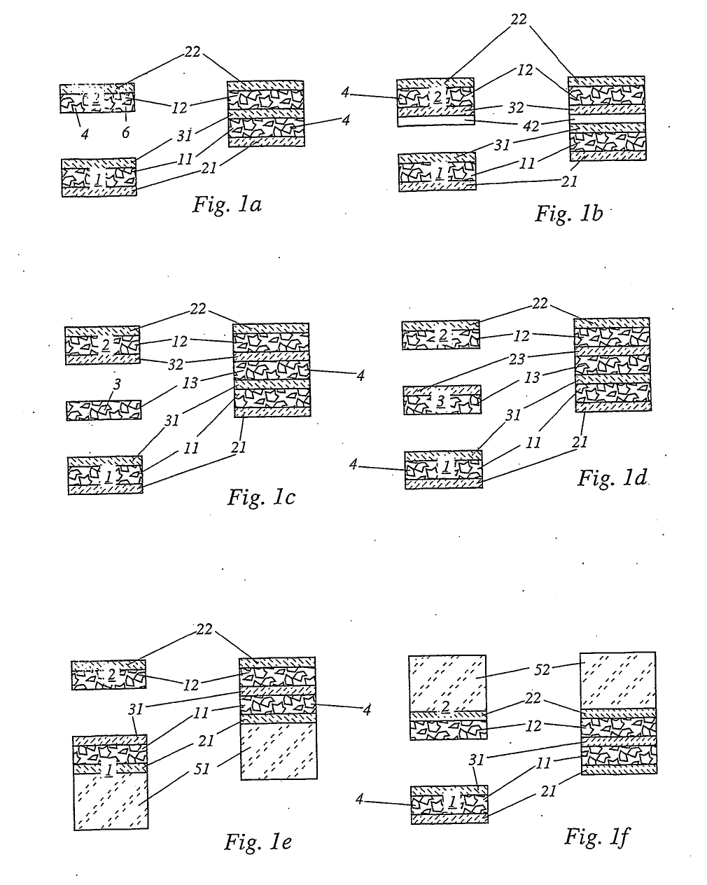

FIGS. 1a through 1k show different arrangement variations in principle in the layered construction of polychromatic electroluminescent elements according to the present invention, each once before joining of the electroluminescent films and once afterward. Possible additional insulation or adhesion promoting layers contained in the structure are not shown.

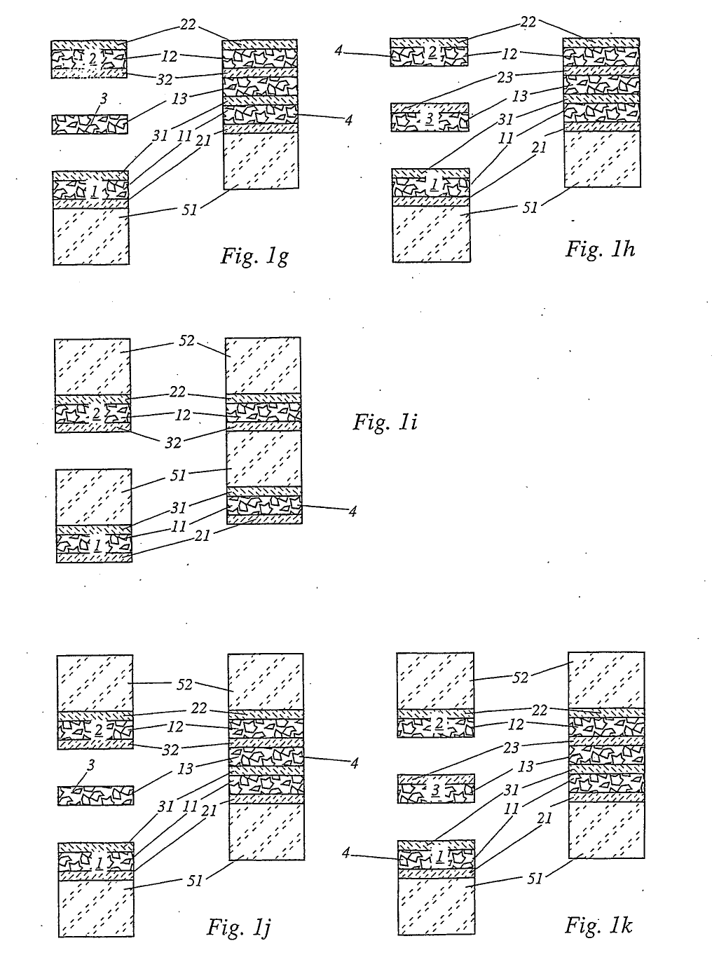

FIG. 2 shows an example of a polychromatic electroluminescent element assembled from three electroluminescent films, before joining of the electroluminescent films and afterward, each electroluminescent film having a stable film substrate.

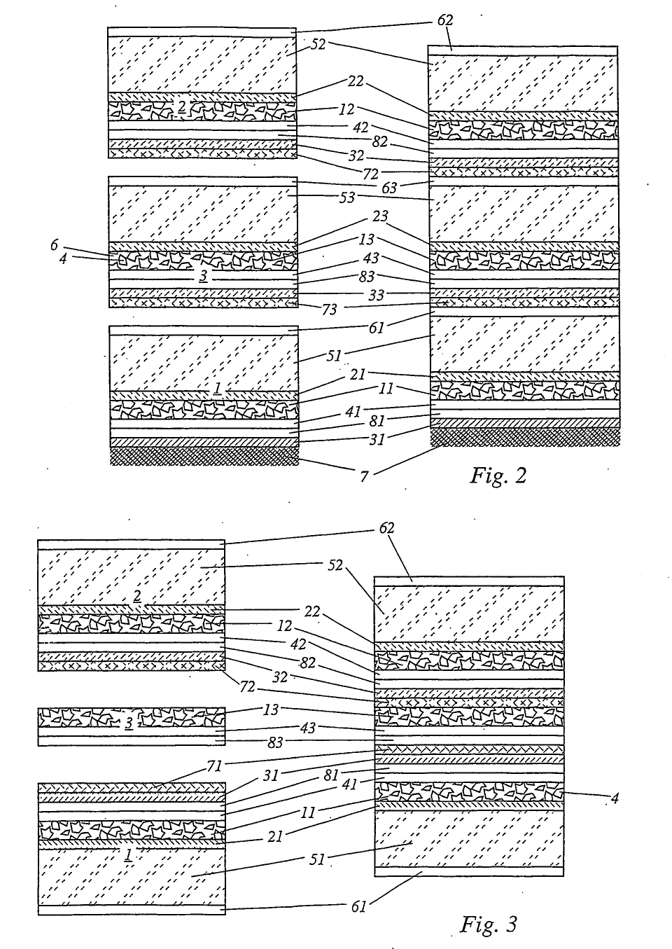

FIG. 3 shows an example of a polychromatic electroluminescent element assembled from three electroluminescent films, before joining of the electroluminescent films and afterward. In this case, the construction is implemented similarly to FIG. 2, but the middle electroluminescent film has no film substrate, rather its film properties originate from the cast matrix of the luminescent layer.

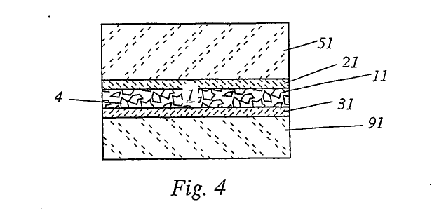

FIG. 4 shows the construction of an electroluminescent film of an especially preferred polychromatic electroluminescent element according to the present invention. Three (or possibly two) similar electroluminescent films, which only differ in their light color, of the type shown are combined with one another in this case.

FIGS. 1a through 1k show examples of different basically possible arrangement variations of the layered construction of polychromatic electroluminescent elements according to the present invention. In this case, the left partial illustration in each case shows the electroluminescent films 1, 2, 3 before being joined, and the right partial illustration shows the layered construction of the polychromatic electroluminescent element resulting afterward. In addition, further layers, particularly dielectric and/or insulation or adhesion promoting layers may be contained in the particular construction, which are not shown for the sake of clarity. The adhesion promoting layers are used for bonding the electroluminescent films to one another. Color-filtering or color-converting layers and imprints (not shown) may also be contained in order to generate a desired color impression. These may also be provided over only a part of the area to achieve certain graphic designs.

Each electroluminescent film 1, 2, 3 has a luminescent layer 11, 12, 13 having disperse electroluminophores 4, these preferably being cast films in whose film matrix 6 the electroluminophores 4 are embedded. Extruded films are also possible, but these are less advantageous because of a distribution of the electroluminophores which is often unfavorable. In particular, the illustration of the electroluminophores 4 is to be understood as purely schematic. In practice, particles which approximate the spherical shape as much as possible are sought. Electroluminophores are typically sensitive to the effect of moisture. Therefore, additional layers, which assume the function of a moisture barrier and/or vapor barrier, are usually integrated in the layered construction of typical electroluminescent elements. Corresponding layers may also be integrated in the construction of polychromatic electroluminescent elements according to the present invention. However, these may largely be dispensed with if microencapsulated electroluminophores 4 are used. The microencapsulation is typically oxidic or nitridic, but an organic microencapsulation or a diamond-like carbon encapsulation is also conceivable.

FIG. 1a shows an especially simple construction of a polychromatic electroluminescent element according to the present invention. The first electroluminescent film 1 has a (largely transparent or reflecting opaque, depending on the application) electrode layer 21 and a largely transparent back electrode layer 31. Together with the first luminescent layer 11 positioned between them, these form a first electroluminescent capacitor. The second luminescent layer 12 belonging to the second electroluminescent film is provided with only one largely transparent electrode layer 22. In the completely assembled polychromatic electroluminescent element, the electrode layer 22 and the second luminescent layer 12 form a second electroluminescent capacitor together with the back electrode layer 31 of the first electroluminescent film 1. Because the electroluminophores 4 of the first luminescent layer 11 and the second luminescent layer 12 each luminesce in a different color, different light colors of the polychromatic electroluminescent element may be achieved through additive color mixing, by setting the electrical alternating fields between the two electroluminescent capacitors differently. Of course, this is only possible if at least the second luminescent layer 12 is largely transparent. Even white light may thus be produced with suitably selected electroluminophores 4, such as blue electroluminophores 4 in the first luminescent layer 11 and orange-colored electroluminophores 4 in the second luminescent layer 12 and suitable electrical activation.

The polychromatic electroluminescent element illustrated in FIG. 1b is largely constructed like the polychromatic electroluminescent element in FIG. 1a. However, to achieve better controllability, the second luminescent layer 12 has its own back electrode layer 32 here. Back electrode layer 32 and electrode layer 22 may also be exchanged in this case. The construction illustrated in FIG. 1b makes it necessary to provide an insulating layer 42 at the bonding face between first electroluminescent film 1 and second electroluminescent film 2 in order to avoid short-circuits.

A polychromatic electroluminescent element having three electroluminescent films 1, 2, 3 is illustrated in each of FIGS. 1c and 1d. Each of the luminescent layers 11, 12, 13 emits in a different color because of different electroluminophores 4, so that the multiplicity of colors achievable using additive color mixing is much greater. If red, blue, and green (RGB) electroluminophores 4 are used, the presentation of the entire color spectrum is possible in principle. However, red electroluminophores are typically not used, since they contain cadmium, which is toxic. A red light color may also be achieved using color-converting or color-filtering substances, however. The at least four electrodes required for a “three color” construction may be distributed differently before the joining. In addition to electrode layer 21 and back electrode layer 31 on the first electroluminescent film 1, an electrode layer 22 and a back electrode layer 32 may also be positioned on the second electroluminescent film 2, as shown in FIG. 1c, while a separate electrode layer is not absolutely necessary for the third, middle electroluminescent film 3. The second electroluminescent film 2 may also not have a back electrode layer 32, for this purpose the third electroluminescent film 3 is provided with its own electrode layer 23.

The construction illustrated in FIG. 1e and FIG. 1f essentially corresponds to the construction shown in FIG. 1a. However, the first electroluminescent film 1 (FIG. 1e) or the second electroluminescent film 2 (FIG. 1f) has a stable film substrate 51, 52 here. The corresponding electrode layer 21, 22, preferably made of ITO (indium-tin oxide) may be sputtered or vapor deposited on the film substrate 51, 52 using vacuum technology, for example. The transparent or at least partially transparent film substrate 51, 52 comprises a polymer or copolymer film, made of polycarbonate (PC) or polyalkylene terephthalates or polyamide (PA) or polyacrylate or polymethacrylate or polymethyl methacrylate (PMMA) or polyurethane (PUR) or polyoxymethylene (POM) or ABS-graft polymers or polyolefins, such as polyethylene (PE) or polypropylene (PP), or polystyrene (PS) or polyvinyl chloride (PVC) or polyimide (PI) or polyether imides (PEI) or polyether or polyether ketones (PEK) or polyvinyl fluoride (PVF) or polyvinylidene fluoride (PVdF) or similar films which have high transparency in the optically visible wavelength range. Films made of polyethylene terephthalate (PET) are especially suitable. Since the film substrate 51, 52 functions as a stabilizing carrier, the corresponding luminescent layer 11, 12 no longer absolutely requires special intrinsic stability, so that the luminescent layer 11, 12 may be implemented not only as a (cast) film, but rather instead also as a screenprinted layer or the like.

FIG. 1g and FIG. 1h show a construction corresponding to FIG. 1c and/or FIG. 1d, the first electroluminescent film 1 having a film substrate 51 of the type described above.

The construction of the polychromatic electroluminescent element illustrated in FIG. 1i largely corresponds to the construction illustrated in FIG. 1b, both electroluminescent films 1, 2 having a film substrate 51, 52 of the type described above. Thus, two almost identical electroluminescent films 1, 2, which only differ through the color of their electroluminophores 4, may be used. By adding a third electroluminescent film (not shown) which only differs through its light color, an RGB arrangement for representing the entire color spectrum is also possible.

FIG. 1j and FIG. 1k show a construction corresponding to FIG. 1g and/or FIG. 1h, in addition to the first electroluminescent film 1, the second electroluminescent film 2 also having a film substrate 52 of the type described above.

In addition to the variations illustrated in FIG. 1a through FIG. 1k, “mixed forms” produced therefrom and further arrangements according to the present invention are also possible.

The “back” electrode layers 21, 22, 23, 31, 32, 33 are typically contacted around the entire edge of the electrode area using annular conductors led around the electrode area. This has advantage that in spite of the not insignificant resistance per unit area of the thin electrode layers 21, 22, 23, 31, 32, 33, potential differences which are too great are not implemented over the area and therefore the homogeneous luminescent effect is supported. Furthermore, individual electroluminescent films 1, 2, 3, but also the entire polychromatic electroluminescent element, may be divided into segments, individual segments each being electrically contacted separately and also being able to be activated separately, in order to be used as a segmented display for representing different patterns and/or graphics or even characters.

A somewhat more detailed illustration of a “three color” (RGB) emitting polychromatic electroluminescent element is shown in FIG. 2. In this case as well, the left partial illustration shows the electroluminescent films 1, 2, 3 before being joined, and the right partial illustration shows the layered construction of the polychromatic electroluminescent element resulting afterward.

A contact adhesive layer 7 is provided on the first, lowermost electroluminescent film 1 for simplified application to a substrate. Otherwise, the individual electroluminescent films 1, 2, 3 are as identical as possible and essentially constructed corresponding to FIG. 1i (the luminescent layers 11, 12, 13 merely emit in a different color in each case, obviously, expediently red, blue, and green):

A polyester film 51, 52, 53 used as a film substrate 51, 52, 53, for example, of a thickness between 100 μm and 250 μm, preferably between 125 μm and 175 μm, is provided with an electrically conductive and largely transparent coating in the form of an indium-tin oxide (ITO) coating 21, 22, 23 used as an electrode layer 21, 22, 23. This electrode layer 21, 22, 23 may be textured conventionally using cutting-scratching plotters or using etching or through the effect of lasers according to the desired implementation of multiple segments and the corresponding terminal wiring or may be used with its surface whole. It is also possible to partially ablate the electrode layer 21, 22, 23 internally in the finished or semifinished electroluminescent film 1, 2, 3 or even the finished or partially finished polychromatic electroluminescent element using a laser beam and thus texture and/or contour it.

Furthermore, busbars, i.e., more conductive wiring elements (not shown) may be produced using screen printing and/or using silver conductive pastes and/or copper conductive pastes and/or carbon conductive pastes.

In the production, the particular luminescent layer 11, 12, 13 is preferably produced using screen printing in the desired graphic implementation in the form of electroluminophores 4 and/or EL pigments 4 dispersed in a transparent polymer matrix 6. Depending on the desired emission color, suitable EL pigments 4 or EL pigment mixtures 4 are used and/or suitable color-converting and/or color-filtering substances are admixed with the binder of the matrix 6. In principle, color-converting and/or color-filtering effects may also be caused by a corresponding layer 61, 62, 63 being applied and/or a corresponding film being laminated on the top of the substrate 51, 52, 53 using further printing.

It may be expedient to apply a dielectric layer 41, 42, 43 to the luminescent layer 11, 12, 13. If a screen printing process is used, a second dielectric layer 81, 82, 83 is advantageously applied, through which small flaws and/or micro air inclusions are covered and the insulation characteristic is improved.

In contrast to typical EL film structures, according to the present invention, transparent polymer dielectric layers 41, 42, 43, 81, 82, 83 are preferably used, the lowest possible layer thickness having to be ensured, since typically additives which increase the relative dielectric constant may not be added, because additives of this type, which comprise fine barium titanate pigments, for example, would influence the transparency very strongly and would typically cause an undesired opacity with stronger reflection.

Preferably, the (largely) transparent back electrode 31, 32, 33 is produced using screen printing in the form of an intrinsically conductive polymer layer and/or a layer having metal oxides, such as indium-tin oxide (ITO) or antimony-tin oxide (ATO). Through application using screen printing, the back electrode 31, 32, 33 may be designed largely freely in regard to graphics and functions. Since electrically conductive screen printing pastes typically do not have good area conductivity, busbars (not shown) are printed on the edges and/or around the circumference using pastes having good electrical conductivity, especially with larger areas. These busbars may also be used for leading out the electrical terminals.

In principle, however, the back electrode 31, 32, 33 may also be produced over the entire area using doctor blades, roll coating, curtain casting, spraying, and similar methods.

As the last individual step in the production of the individual electroluminescent films 1, 2, 3, adhesion promoting layers 72, 73 may be applied, which cause and/or improve the bond of the individual electroluminescent films 1, 2, 3. Primarily, a transparent polymer bonding layer is understood as an adhesion promoting layer 71, 72, 73. This may cause a bond in the cold adhesive method after removal of a protective film and application using printing. However, hot adhesive coatings may also be used, which cause an adhesive bond under temperature and pressure. Since a bond which is as optically transparent as possible is required, the adhesion promoting layers 71, 72, 73 must be transparent and the bond must be implemented without air inclusions. Furthermore, unevenness of the preceding layers is also to be compensated for by the adhesion promoting layer 72, 73

In general, the bonding of the electroluminescent films 1, 2, 3 may be performed flatly or in elements using cold lamination and/or hot lamination. Alternately, the bonding may also only be performed punctually or in strips, since the three electroluminescent films 1, 2, 3 are possibly fixed together without this during installation in a corresponding application.

If double-sided light emission is desired, the dielectric layers 41, 81 and the back electrode 31 of the lowermost electroluminescent film must be implemented as largely transparent, while for single-sided light emission on top, one or more of the layers cited is preferably implemented as opaque and/or reflective, and the back electrode 31 may additionally assume diverse wiring functions.

According to the present invention, the arrangement blue-red-green, green being positioned on the light exit side, has been ascertained to be very efficient for generating the largest possible multiplicity of colors and particularly for generating the color white. Other arrangements and/or another sequence may also be used depending on the use of the EL pigments 4 and/or the combination of EL pigments 4 and the use of corresponding color-converting and/or color-filtering substances.

As already noted above, in principle, instead of the use of a largely dimensionally stable film substrate 51, 52, 53, the luminescent layer 11, 12, 13 may also be formed by an EL cast film. EL cast films are understood as thin films produced from solution using a casting method, in which the electroluminescent pigments are embedded at a diameter of less than 30 μm, preferably less than 20 μm, especially preferably less than 15 μm. EL cast films of this type are relatively dimensionally stable and may preferably be coated with electrode layers 21, 22, 23 in roll-to-roll methods using vacuum technology or screen printing or doctor blades or roll coating or spraying or curtain casting. With a corresponding embodiment of the luminescent layers 11, 12, 13, the application of the dielectric layers 41, 42, 43, 81, 82, 83 may be dispensed with and therefore very good transparency and electrical disruptive strength and outstanding surface planarity may be achieved. The disadvantage of this method is the implementation of the luminescent layers 11, 12, 13 over the entire area and thus the higher costs due to an increased proportion of EL pigments 4.

FIG. 3 shows an alternative embodiment, the reference numbers of layers corresponding to FIG. 2 being maintained. As shown in FIG. 3 and already noted above, instead of using a largely dimensionally stable film substrate 53, the middle electroluminescent film 3 may be made using an EL cast film as the luminescent layer 13. The other electroluminescent films 1, 2 may also be designed in principle without film substrate 51, 52 in the event of appropriate production of the luminescent layers 11, 12.

An advantage of the arrangement shown in FIG. 3 is the savings of one or two electrode layers. In this illustration, a mirror-image construction of the upper and lower electroluminescent films 1, 2 is shown, and the middle electroluminescent film 3 is implemented having a cast luminescent layer 13 and two dielectric layers 43, 83. These two dielectric layers 43, 83 may alternately also be positioned on both sides of the luminescent layer 13 and may additionally be used for the adhesion promotion and may contain color-converting and/or color-filtering additives. The adhesion promoting layers 71, 72 of the upper and lower electroluminescent films 1, 2 may be dispensed with, and the back electrodes 31, 32 of the upper and lower electroluminescent films 1, 2 form the electrodes for the middle EL capacitor.

The construction shown in FIG. 4 of an electroluminescent film 1 has been shown to be an especially favorable compromise of reliable function and good producibility. Three (possibly also two) similar electroluminescent films of the type shown, which only differ in their light color, are combined with one another in this case to form a polychromatic electroluminescent element according to the present invention. The electroluminescent film 1 essentially comprises a film substrate 51 made of PET or another plastic, on which the electrode layer 21 is vapor deposited or sputtered, a luminescent layer 11 and a transparent back electrode 31, applied thereto through screen printing, which is laminated in using the insulating film 91. Substrates which do not comprise a plastic film, but rather a ceramic material, such as glass, are also conceivable in principle.

1. A polychromatic electroluminescent element, having
a first electroluminescent film (1), which has a first electrode layer (21), a first luminescent layer (11) having disperse electroluminophores (4), and a back electrode layer (31), and
a second electroluminescent film (2), which has a second electrode layer (22) and a second luminescent film (12) having disperse electroluminophores (4),
wherein the second electroluminescent film (2) is implemented to emit light of a different color than the first electroluminescent film (1).

2. The polychromatic electroluminescent film according to claim 1, wherein the second electroluminescent film (2) also has a back electrode layer (32).

3. The polychromatic electroluminescent element according to claim 2, also having a third electroluminescent film (3), which has a third luminescent layer (13) having disperse electroluminophores (4).

4. The polychromatic electroluminescent element according to claim 3, wherein the third electroluminescent film (3) also has an electrode layer (23).

5. The polychromatic electroluminescent element according to claim 4, wherein the third electroluminescent film also has a back electrode layer (33).

6. The polychromatic electroluminescent element according to claim 1, wherein at least one electroluminescent film (1, 2, 3) has a film substrate (51, 52, 53), which is provided with one of the electrode layers (21, 22, 23).

7. The polychromatic electroluminescent element according to claim 6, wherein at least two of the electroluminescent films (1, 2, 3) each have a film substrate (51, 52, 53), each of which is provided with one of the electrode layers (21, 22, 23).

8. The polychromatic electroluminescent element according to claim 7 having three electroluminescent films (1, 2, 3), all three electroluminescent films (1, 2, 3) each having a film substrate (51, 52, 53), each of which is provided with one of the electrode layers (21, 22, 23).

9. The polychromatic electroluminescent element according to claim 6, wherein at least one film substrate (51, 52, 53) is made of polyethylene terephthalate.

10. The polychromatic electroluminescent element according to claim 6, wherein at least one of the electrode layers (21, 22, 23) is vapor deposited or sputtered on the associated film substrate (51, 52, 53) using vacuum technology.

11. The polychromatic electroluminescent element according to claim 1, wherein at least one of the luminescent layers (11, 12, 13) is implemented as a cast film.

12. The polychromatic electroluminescent element according to claim 1, wherein the disperse electroluminophores (4) are of inorganic nature.

13. The polychromatic electroluminescent element according to claim 12, wherein the disperse electroluminophores (4) are microencapsulated.

14. The polychromatic electroluminescent element according to claim 1, which contains at least one additional dielectric layer (41, 42, 43).

15. The polychromatic electroluminescent element according to claim 1, wherein the electroluminescent films (1, 2, 3) are bonded to one another by at least one adhesive layer (71, 72, 73).

16. The polychromatic electroluminescent element according to claim 1, wherein at least one layer of the polychromatic electroluminescent element contains at least one of a group consisting of color-converting organic additives, color-filtering organic additives, color-converting inorganic additives and color-filtering inorganic additives.

17. The polychromatic electroluminescent element according to claim 1, wherein each back electrode layer (31, 32, 33) is implemented as largely transparent.

18. The polychromatic electroluminescent element according to claim 1, wherein the first electrode layer (21) or the back electrode layer (31) of the first electroluminescent film (1) is implemented as opaquely reflective.

19. The polychromatic electroluminescent element according to claim 1, wherein at least one of the electrode layers (21, 22, 23) is at least partially contoured using a laser beam.

20-26. (canceled)

27. The polychromatic electroluminescent element according to claim 1, wherein at least one of the back electrode layers (31, 32, 33) is at least partially contoured using a laser beam.

28. The polychromatic electroluminescent element according to claim 1, wherein each electroluminescent film (1, 2, 3) may be electrically activated separately.

29. The polychromatic electroluminescent element according to claim 19 having 3 electroluminescent films (1, 2, 3), wherein one of the electroluminescent films (1, 2, 3) is implemented to emit red light, one of the electroluminescent films (1, 2, 3) is implemented to emit green light, and one of the electroluminescent films (1, 2, 3) is implemented to emit blue light.

30. The polychromatic electroluminescent element according to claim 1, wherein at least one of the electroluminescent films (1, 2, 3) is subdivided into segments which may be electrically activated independently of one another.

31. A method for producing a polychromatic electroluminescent element, wherein at least two electroluminescent films (1, 2, 3) are joined.

32. The method for producing a polychromatic electroluminescent element according to claim 31, wherein three electroluminescent films (1, 2, 3) are joined.

33. The method according to claim 31, wherein the joining is performed using one of the group consisting of cold lamination, hot lamination and vacuum lamination.

34. The method according to claim 31, wherein at least one layer of the polychromatic electroluminescent element is processed using a laser beam after the joining.
